(19) United States
(12) Patent Application Publication
(10) Pub. No.: US 2011/0086246 A1
(43) Pub. Date: Apr. 14, 2011

(54) SEMICONDUCTOR DEVICE COMPRISING A SOLAR CELL, METHOD OF MANUFACTURING A SEMICONDUCTOR DEVICE AND APPARATUS COMPRISING A SEMICONDUCTOR DEVICE

(75) Inventors: Yukiko Furukawa, Kimitsu (JP); Johan Hendrik Klootwijk, Eindhoven (NL)

(73) Assignees: NXP B.V., Eindhoven (NL); KONINKLIJKE PHILIPS ELECTRONICS N.V., EINDHOVEN (NL)

(21) Appl. No.: 12/996,814

(22) PCT Filed: Jun. 8, 2009
(86) PCT No.: PCT/IB09/52426

§ 371 Date: Dec. 8, 2010

(30) Foreign Application Priority Data
Jun. 9, 2008 (EP) 08157874.2
Jun. 8, 2009 (IB) PCT/IB2009/052426

(51) Int. Cl. H01M 10/42; H01L 31/18; H01M 16/00; H01L 31/06

(52) U.S. Cl. 429/7; 438/19; 429/9; 257/E31.11

(57) ABSTRACT

The invention relates to a semiconductor device includes a substrate (1000; 2000), a solar cell (1910; 2910) formed on the substrate (1000; 2000) and a battery (1900; 2900) formed on the substrate, the battery comprising a plurality of trench batteries in a plurality of corresponding trenches (1400; 2400) in the substrate (1000; 2000). The solar cell can include a silicon solar cell (1910) comprising a plurality of p-n junctions for, during use, receiving incident light and converting at least part of the received incident light into an electrical current. Alternatively, the solar cell can include an electrochemical cell (2910) for, during use, receiving incident light and converting at least part of the received incident light into an electrical current. The invention further relates to a manufacturing method for a semiconductor device. The invention further relates to an apparatus comprising a semiconductor device.

### FIELD OF THE INVENTION

The invention relates to a semiconductor device comprising a solar cell. The invention further relates to a multi-chip package comprising a semiconductor device. The invention further relates to method of manufacturing a semiconductor device. The invention further relates to an apparatus comprising a semiconductor device.

### BACKGROUND OF THE INVENTION

Personal portable devices have become widely used for a variety of applications. E.g., it has become common practice for people to always carry at least a mobile phone, and people can substantially always be reached on their mobile phones. However, portable devices need to be supplied with electricity to be able to function. Hereto, portable devices usually comprise a rechargeable battery, which may be charged using a charger connecting to a power supply, generally a mains supply. When the battery is exhausted, the device cannot be used, and needs to be recharged, requiring a connection to the power supply. This may be inconvenient in practice.

To overcome this inconvenience, some portable devices are equipped with a solar cell. The portable device can then be operated without a battery as long as the solar cell receives sufficient light to produce the required amount of power. Additionally, a battery may be included in the portable device, allowing the device to function in the absence of light or at low light levels. The battery may then be charged by the solar cell when the device is not used, or when the solar cell produces more electrical power than consumed by the device. Moreover, a combination of a battery and a solar cell may relax the performance peak requirement of the solar cell, as the battery may substantially supply the device whereas the solar cell only needs to charge the battery.

However, such combinations may be too large to fit conveniently in some devices when using a separate solar cell and a separate battery, e.g. to fit a wrist watch or a wireless sensor for a wireless sensor network. Integrated systems of a battery and a solar cell have been proposed, with a battery connected to a solar cell forming a single package. E.g., thin-film silicon solar cells integrated with a thin-film battery have been proposed. However, the power requirements for various applications may still be too high to meet with an acceptable the size of such devices. E.g., a large thin-film battery may be required to match the energy requirements of a device. Also, the cost may be too high for various applications, as the cost of a thin-film silicon solar cell of a sufficient size to meet energy conversion requirements for charging the battery in a reasonable time period may be large and this cost may dominate the cost of the integrated device when a single-crystalline solar cell is used.

Hence, it is a problem of the known solar cell systems with battery backup that the requirements can not be achieved with an acceptable balance between performance, cost and size.

### SUMMARY OF THE INVENTION

The present invention aims to provide a semiconductor device comprising a solar cell and a battery with a large storage capacity. The invention further aims to provide a multi-chip package comprising such a semiconductor device. The invention further aims to provide a method of manufacturing such a semiconductor device. The invention further aims to provide an apparatus comprising such a semiconductor device.

For this purpose, the semiconductor device according to the invention comprises:
a substrate,
a solar cell formed on the substrate,
a battery formed on the substrate, the battery comprising a plurality of trench batteries in a plurality of corresponding trenches in the substrate.

The battery and solar cell are formed on the same substrate to form a highly integrated and small device.

The trench batteries provide a large energy storage capacity to the semiconductor device. The capacity of trench batteries may be two or more orders of magnitude larger than of a thin-film battery on a similar substrate area. Alternatively to the plurality of trench batteries in a plurality of corresponding trenches in the substrate, the battery may comprise a plurality of pillar batteries on a plurality of corresponding pillars on the substrate. In the remainder of this application and in the claims, both the trench batteries as well as the pillar batteries will be referred to as trench batteries.

The battery may be efficiently charged with the solar cell.

The use of a battery with a large energy storage capacity may allow to use a relatively small sized substrate. This may be advantageous, especially when the substrate comprises a relatively expensive part of the semiconductor device. The use of such a battery may e.g. allow a sufficiently small single-crystalline substrate for forming a solar cell with a sufficiently low cost, whereas a thin-film battery would result in a too large and hence too expensive device.

In an embodiment, the solar cell comprises a silicon solar cell comprising a plurality of p-n junctions for, during use, receiving incident light and converting at least part of the received incident light into an electrical current.

The silicon solar cell may e.g. be a crystalline-silicon solar cell, an amorphous-silicon solar cell or a compound semiconductor solar cell.

In an embodiment, the solar cell comprises an electrochemical cell for, during use, receiving incident light and converting at least part of the received incident light into an electrical current.

In an embodiment, the solar cell and the battery are electrically connected for, during use of the semiconductor device, transporting electrical energy generated by the solar cell to the battery.

In a further embodiment, the solar cell and the battery are electrically connected via the substrate.

Thus the need for an external connection between the solar cell and the battery is omitted. This may allow a further reduction in size and may allow a more robust device.

In an embodiment, the semiconductor device further comprises:
an integrated circuit monitoring element capable of, during use,
monitoring at least one condition of a group consisting of a condition of the solar cell, a condition of the battery and a condition of a relation between the solar cell and the battery, and
providing monitoring information from monitoring at least one condition.

E.g. the monitor unit may monitor whether the solar cell is generating electricity, the level to which the battery is charged or whether the solar cell is charging the battery.

In an embodiment, the semiconductor device further comprises: an integrated circuit power regulator element capable of, during use,
controlling an electrical power provided from at least one of the solar cell and the battery.

The semiconductor device thus controls the powering of external devices, or allows to power other internal functional units integrated in the semiconductor device.

In an embodiment, the semiconductor device further comprises a sensor, the sensor being electrically connected to the solar cell and to the battery.

The sensor may thus be powered from the solar cell and/or the battery. The sensor may be any type of suitable sensor.

For example, the sensor may be arranged for sensing an external signal, such as a radio signal, an electrical field, a magnetic field, or an acoustic signal. The sensor may be arranged for sensing an ambient condition, such as e.g. a temperature, a light level, a spectral component of light, a humidity, an atmospheric pressure, a chemical composition or a presence of a chemical component such as a specific gas, e.g. a poisonous gas. The sensor may be arranged for sensing an parameter of a body, arranged closely to the sensor or in contact with the sensor, such as a body temperature. The body may be a human body. The body may be a mechanical body, e.g. a part of an apparatus for sensing a temperature of the part of the apparatus. The sensor may be arranged with a part of an automobile, for e.g. sensing exhaust gas, sensing indoor gas, sensing a speed of the automobile, sensing an acceleration, sensing a vibration, sensing an air pressure of a tire, or sensing a wear of a component of the automobile.

In further embodiments, the semiconductor device further comprises an antenna, the antenna being electrically connected to the sensor.

The antenna may be arranged for, during use, providing a wireless communication with a wireless sensor network.

In an embodiment, the substrate has a first surface and a second surface, opposite to the first surface, wherein the battery and the solar cell are both formed at the first surface.

In an embodiment, the substrate has a first surface and a second surface, opposite to the first surface, wherein the solar cell is formed at the first surface and the battery is formed at the second surface.

In an embodiment, the substrate is a silicon substrate.

The use of a silicon substrate may allow an efficient battery. E.g., the silicon may intercalate Lithium from the battery efficiently.

The use of a silicon substrate may allow a convenient manufacturing, using standard IC technology processes for either the battery, or the solar cell or both the battery and the solar cell. The use of a silicon substrate may allow a convenient integration with e.g. other semiconductor devices.

In an embodiment, the silicon substrate is a single-crystalline silicon substrate.

The use of a silicon substrate may allow an easy integration with other integrated circuits, such as active devices, or even a complete processor.

In an embodiment, the battery has a storage capacity in a range of 0.1-10 mC/mm².

In an embodiment, each of the trench batteries of the plurality of trench batteries has a trench diameter and a trench depth, with the trench diameter in a range of 5-25 μm and an aspect ratio in a range of 10-100, the aspect ratio being the ratio between the trench depth and the trench diameter.

Another aspect of the invention relates to a multi-chip package (MCM) comprising a semiconductor device as described above and a further semiconductor device electrically connected to the semiconductor device and being, during use, energized from the semiconductor device.

With such a package, an application specific package is provided. The semiconductor device with the battery and solar cell may be applied in a wide range of different application specific packages, whereas the further semiconductor device may be specifically designed and manufactured for the specific application. This may allow to create a cost-efficient application specific package.

Another aspect of the invention relates to a method of manufacturing a semiconductor device comprising a solar cell and a battery, the method comprising:
providing a substrate;
forming the solar cell on the substrate; and
forming the battery as a plurality of trench batteries to a plurality of corresponding trenches in the substrate.

The substrate may be provided with trenches formed in the substrate. Alternatively, the substrate may be provides without the trenches and the method may further comprise forming the plurality of trenches in the substrate.

In an embodiment, the method further comprises:
forming an integrated circuit on the substrate, wherein at least one of forming the integrated circuit on the substrate and forming the solar cell on the substrate comprises one or more high-temperature treatments; and
wherein at least part of forming the battery is performed after all high-temperature treatments.

In an embodiment, forming the solar cell is at least partly performed before forming the battery.

As some of the process stages of forming the battery may be incompatible with some of the process stages of forming the solar cell, it may be advantageous to form the battery after forming the solar cell, or to at least perform the incompatible process stages in forming the solar cell before forming the battery. E.g., an implanting stage comprising a high-temperature treatment for diffusion of the implants while manufacturing the p-n junctions of a silicon solar cell may be performed before providing a reactive layer, e.g. comprising lithium, while manufacturing the battery.

In an embodiment:
the solar cell is formed onto a first side of the substrate in a first IC-process, the solar cell comprising a silicon solar cell comprising plurality of p-n junctions for, during use, receiving incident light and converting at least part of the received incident light into an electrical current;
the battery is formed onto the other side of the substrate in a second IC-process.

This allows to form a silicon solar cell on one side of the substrate and the trench battery on the other side of the substrate.

In an embodiment:
the solar cell is formed onto a first side of the substrate in a first IC-process, the solar cell comprising an electrochemical cell for, during use, receiving incident light and converting at least part of the received incident light into an electrical current;
the battery is formed onto the other side of the substrate in a second IC-process.

This allows to form an electrochemical solar cell on one side of the substrate and the trench battery on the other side of the substrate.

In an embodiment, forming the solar cell is at least partly performed after forming the battery.

The electrochemical solar cell may e.g. be formed after forming the battery.

In an embodiment,
the battery is formed onto a first side of the substrate in a first IC-process;
the solar cell is formed in a second IC process, the solar cell comprising an electrochemical cell for, during use, receiving incident light and converting at least part of the received incident light into an electrical current.

This allows to form a battery on the first side of the substrate, and to subsequently form an electrochemical solar cell. Forming the electrochemical solar cell may be performed on the same side as the battery. Forming the electrochemical solar cell may alternatively be performed on the other side of the substrate as the battery.

In an embodiment, the method further comprises forming an integrated circuit monitoring element capable of, during use,
monitoring at least one condition of the group consisting of a condition of the solar cell, a condition of the battery and a condition of a relation between the solar cell and the battery, and
providing monitoring information from monitoring the at least one condition.

In an embodiment, the method further comprises forming an integrated circuit power regulator element capable of, during use,
controlling an electrical power provided from the solar cell and the battery.

In an embodiment, the method further comprises forming a sensor device being arranged for, during use:
being powered from at least one of the solar cell and the battery,
sensing a condition, and
producing a sensor signal.

The condition may e.g. be associated with a chemical composition, a presence of a specific chemical, a speed, an acceleration, a vibration, an air pressure, such as the air pressure in a tire of a vehicle, a blood pressure, a humidity, a temperature, an electrical field, a magnetic field, acoustics, a light level or a spectral component of light. The sensor signal may be an electrical signal.

In an embodiment of the method, the substrate is a silicon substrate.

Another aspect of the invention relates to an apparatus comprising a semiconductor device as described above.

The apparatus may e.g. be a portable personal apparatus such as a mobile phone, an MP3-player, a portable gaming device. The apparatus may e.g. be a wireless sensor for use in a wireless sensor network. The apparatus may e.g. be an tire pressure sensor for use with an air tire of an automobile.

The present invention considers also any combination of elements and features mentioned in the present disclosure with one or more other elements of features mentioned there. Thus any combination is considered as part of the present invention.

### BRIEF DESCRIPTION OF THE DRAWINGS

The above and other aspects of the invention will be further elucidated and described in detail with reference to the drawings, in which corresponding reference symbols indicate corresponding parts:

FIG. 1a-FIG. 1f schematically shows an embodiment of a method of manufacturing a semiconductor device comprising a silicon substrate, a silicon solar cell and a trench battery;

FIG. 2a-FIG. 2g shows an embodiment of a manufacturing method of a semiconductor device comprising an electrochemical solar cell and a trench battery;

FIG. 3a-FIG. 3g shows an embodiment of an alternative manufacturing method of a semiconductor device comprising an electrochemical solar cell and a trench battery;

FIG. 4a-FIG. 4e shows another embodiment of a manufacturing method of a semiconductor device comprising an electrochemical solar cell and a trench battery;

FIG. 5a-FIG. 5e shows again another embodiment of a manufacturing method of a semiconductor device comprising an electrochemical solar cell and a trench battery;

FIG. 6a and FIG. 6b schematically shows an embodiment of a semiconductor device comprising a solar cell and a trench battery formed on a substrate;

FIG. 7a and FIG. 7b schematically shows another embodiment of a semiconductor device comprising a solar cell and a trench battery formed on a substrate;

FIG. 8a and FIG. 8b schematically shows an embodiment of a semiconductor device comprising a solar cell, a trench battery and CMOS circuitry formed on a substrate;

FIG. 9a and FIG. 9b schematically shows another embodiment of a semiconductor device comprising a solar cell, a trench battery and CMOS circuitry formed on a substrate;

FIG. 10a and FIG. 10b schematically shows an embodiment of a multi-chip package comprising a semiconductor device and a further device;

FIG. 11 shows a mobile phone comprising a semiconductor device;

FIG. 12 shows a wireless sensor comprising a semiconductor device.

### DETAILED DESCRIPTION OF THE DRAWINGS

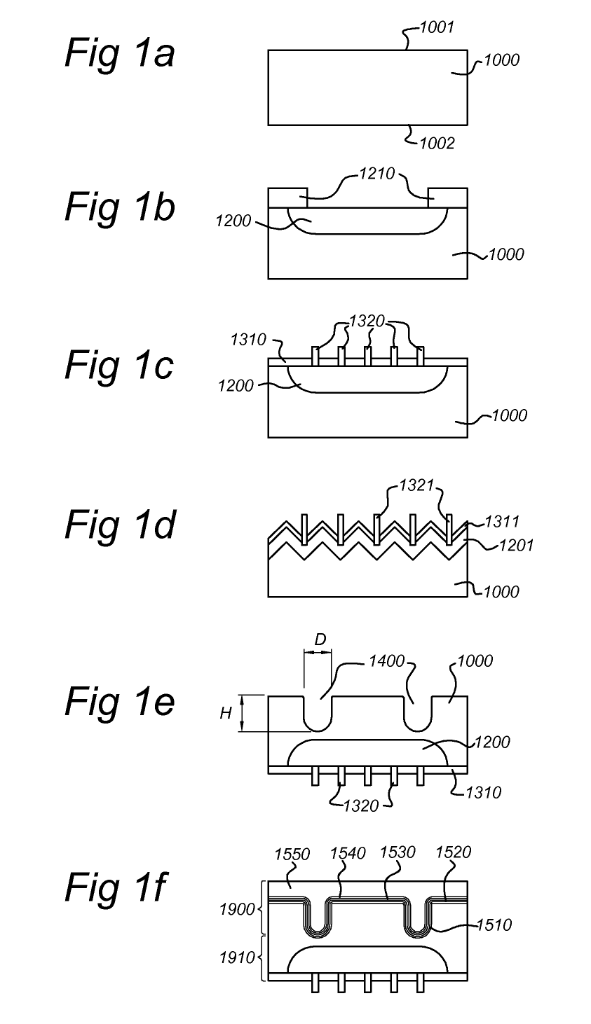

FIG. 1a-FIG. 1f schematically shows an embodiment of a method of manufacturing a semiconductor device comprising a silicon substrate, a silicon solar cell and a trench battery. The embodiment of the method is illustrated by showing the semiconductor device in a plurality of figures FIG. 1a-1f after each of a corresponding process stage 1A-1F.

In process stage 1A, a single-crystalline n-type silicon substrate 1000 is provided with a first surface 1001 and a second surface 1002.

In a next process stage 1B, a photo resist layer 1210 is applied and patterned using a photo-lithography process. After patterning the photo resist layer 1210, a p-type dopant is implanted in exposed parts of the n-type silicon substrate 1000 and a further thermal anneal treatment at a temperature above 900 degrees C., e.g. at a temperature of 900-1000 degrees C., is performed for forming a p-type structure 1200 in the n-type silicon substrate 1000.

Alternatively to forming the p-type structure by implanting the p-type dopant with the subsequent thermal anneal treatment, the p-type structure 1200 may be formed by depositing a p-type dopant on the exposed parts of the substrate surface 1001 with a subsequent thermal diffusion at a temperature of 900-1000 degrees C. from the substrate surface into the substrate.

In a next process stage 1C, a patterned aluminium electrode 1320 is formed by deposition of an aluminium layer and subsequent patterning of the aluminium layer. Also, a passivation coating 1310 is applied on top of the p-type structure and still exposed parts of the first surface 1001 of the n-type silicon substrate 1000. The passivation coating 1310 may be a single layer, which may also function as an anti-reflective coating. The passivation coating 1310 may be a multi-layer stack comprising an anti-reflective coating layer and a passivation layer.

Alternative to providing a flat structure as shown with process stages 1A-1C, an alternative p-type layer 1201, alternative electrodes 1321 and an alternative passivation layer 1311 may be formed with a roughened surface as shown in 1D. This may improve the amount of light absorbed by the solar cell.

A silicon solar cell 1910 comprising a plurality of p-n junctions is thus formed with the n-type silicon substrate 1000 and the p-type structure 1200 for, during use, receiving incident light and converting at least part of the received incident light into an electrical current.

After process stage 1C, or the alternative process stage 1D, the substrate is flipped and processing is continued on its other surface 1002.

In a next process stage 1E, a plurality of trenches 1400 is formed in the substrate on the surface opposite the surface carrying the solar cell 1910.

In this example, each of the trenches has a trench depth H of 200 μm and a trench diameter D of 10 μm, i.e. the trench having an aspect ratio of 20, wherein the aspect is defined as the ratio between the trench depth H and the trench diameter D. Typical alternative trench diameters may be used from e.g. the range of 5-25 μm. Typical alternative aspect ratios may be used from e.g. the range of 10-100. In this example, the trenches are positioned on a square grid with a pitch of 25 μm. Typical alternative pitches may be used from e.g. the range of 10 to 100 μm.

In a next process stage 1F, a battery 1900 is formed by forming a barrier layer 1510 on the silicon substrate and at the inside of the trenches 1400. The barrier layer 1510 may e.g. be formed using sputtering of a titanium nitride barrier layer with a thickness in a range of 50 to 500 nm. The TiN barrier layer 1510 prevents diffusion of lithium from the battery into the silicon substrate 1000 and towards silicon the solar cell 1910. A silicon layer 1520 is deposited on top of the barrier layer 1510 to form an anode of the battery. The silicon layer may have a thickness depending on a targeted capacity of the battery. A solid electrolyte layer 1530 is then deposited on the silicon layer 1520. The solid electrolyte layer 1530 may e.g. have a thickness of 1 μm. The solid electrolyte layer 1530 may comprise LiPON, which may be deposited at 350 degrees C. A cathode layer 1540 is deposited on top of the solid electrolyte layer 1530. The cathode layer may comprise LiCoO₂, which may be deposited by LPCVD and subsequently annealed at 350-700 degrees C. The cathode layer 1540 may have a thickness of 1 μm. Next, a current collector 1540 is applied on the cathode layer 1540. The current collector 1540 may comprise platinum-titanium layer, which may be deposited using atomic layer deposition (ALD). The current connector 1540 may be used for connecting a positive contact lead (not shown).

Layer thicknesses mentioned above are given as examples. Alternative layer thicknesses and alternative suitable materials may be used for e.g. realizing the battery.

The use of the silicon substrate for forming both the silicon solar cell and the trench battery results in a highly compact device. Moreover, the device is also cost-effective. The silicon substrate, which is relatively expensive especially when it is a single-crystalline substrate, is used efficiently. The single-crystalline silicon substrate also results in a highly efficient solar cell, being approximately 1 to 8 times more efficient compared to an amorphous silicon solar cell, a multi-crystalline solar cell or a thin-film silicon solar cell. The substrate may also be a different type of substrate.

The manufacturing method may comprise further processing stages, e.g. providing integrated circuitry to the silicon substrate. E.g. power management circuitry may be added to regulate a voltage of the battery, to prevent an overcharging by the solar cell of the battery.

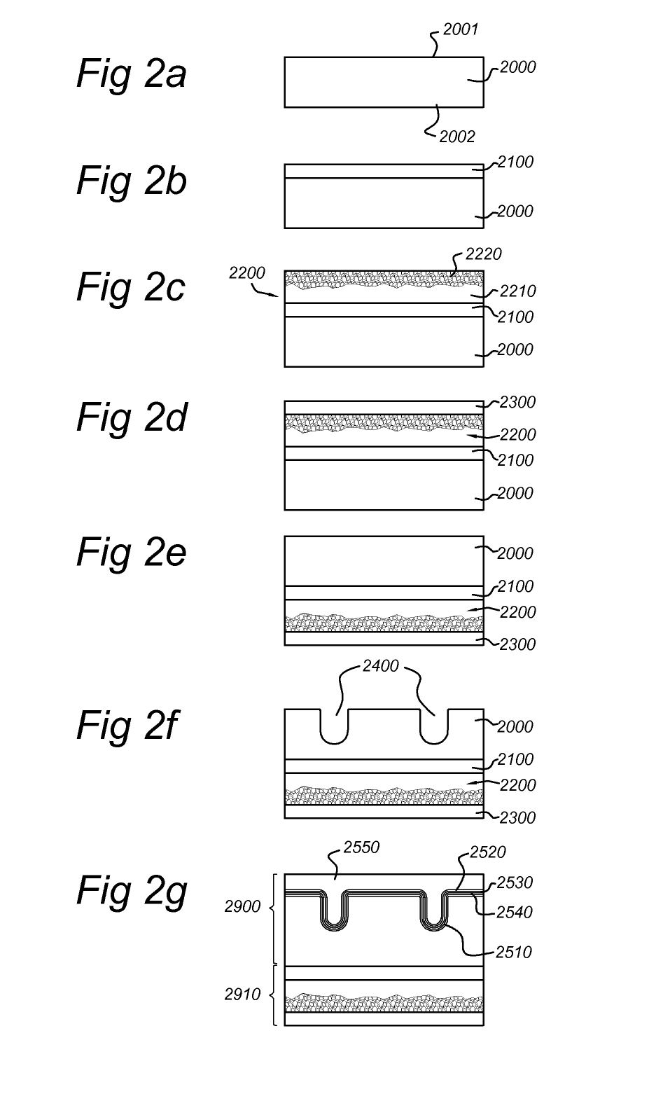

FIG. 2a-FIG. 2g shows an embodiment of a manufacturing method of a semiconductor device comprising an electrochemical solar cell and a trench battery. The embodiment of the method is illustrated by showing the semiconductor device in a plurality of figures FIG. 2a-2g after each of a corresponding process stage 2A-2G.

In process stage 2A, a silicon substrate 2000 is provided. The substrate in this example is a silicon substrate polished on both sides. The substrate has flat surfaces on each side with a first surface 2001 on one side and a second surface 2002 on the opposite side. Alternatively, the substrate may e.g. already be provided with trenches on one surface.

In a next process stage 2B, an electrode 2100 is applied on the silicon substrate 2000 to the first surface 2001. The electrode may e.g. be a platinum layer with a thickness of 200 nm, deposited using e.g. atomic layer deposition (ALD).

In a next process stage 2C, an electrochemical stack 2200 is applied on the electrode 2100, comprising an electrolyte 2210 and a 5-15 μm thick TiO₂ layer with dye-sensitizer 2220. The electrolyte 2210 may be a solid electrolyte with e.g. a thickness of 10-30 μm. The electrolyte may alternatively be a liquid electrolyte in a sealing material.

First, the electrolyte 2210 is applied on the electrode 2100. The solid electrolyte may be applied using spin-coating. The alternative liquid electrolyte may be an I⁻/I₃⁻ system comprising mixtures of iodides such as LiI, NaI, KI, R4NI with I₂ dissolved in a nonprotonic solvent such as a nitrile, e.g. acetonitrile, propionitrile, methoxyacetonitrile or propylenecarbonate. The sealing material may be a copolymer of ethylene and acrylic acid. The solid electrolyte may be a polymerized I⁻/I₃⁻ system or a p-type semiconductor.

Then, the TiO₂ layer with dye-sensitizer 2220 is applied on the solid electrolyte 2210. The TiO₂ is a n-type semiconductor and may act as an electrode. As TiO₂ adsorbs substantially only UV light, the dye-sensitizer is added to adsorb a wider range of light, especially visible light. The dye sensitizer may e.g. comprise a Ru complex photosensitizer N₃ and a black dye.

Instead of TiO₂ with dye-sensitizer, N-doped TiO₂ may be used. As another alternative, a TiN core with a TiO₂ shell material may be used. Using N-doping or TiN results in a wider spectral range of light adsorption than using TiO₂ alone so that the processing of electrochemical solar cell can be simplified.

The use of the above material may specifically be combined with one or more of the other elements and features mentioned throughout this disclosure, such as that of present claims 1, 8 and 13.

In a next process stage 2D, a transparent electrode 2300 is applied on the electrochemical stack 2200. The transparent electrode 2300 may be a conducting polymer, such as PEDOT:PSS, deposited using spin-coating. The transparent electrode 2300 may be Indium Tin Oxide (ITO) deposited by magnetron sputtering at a temperature of approx. 250-350 degrees C. The transparent electrode 2300 may alternatively be e.g. amorphous ITO deposited at room temperature. The transparent electrode 2300 may be ZnO or a-InGaZnO₄ deposited at room temperature by magnetron sputtering.

In a next process stage 2E, the substrate 2000 carrying the electrode layer 2100, the electrochemical stack 2200 and the transparent electrode 2300 is flipped.

In a next process stage 2F, deep trenches 2400 are formed in the second surface 2002 of the silicon substrate using lithography and etching.

In a next process stage 2G, a current collector 2510 of Pt/Ti is formed by ALD on the inner walls of the trenches. A LiCoO₂ cathode layer 2540 is formed on the current collector 2510. A LiPON solid electrolyte layer 2530 is formed on the cathode layer 2540. A silicon anode layer 2520 is formed on the solid electrolyte layer 2530. A current collector layer 2550 is applied on the silicon anode layer 2520.

As a result, the electrochemical solar cell 2910 and the trench battery 2900 are formed on opposite sides of the substrate.

The deposition methods mentioned above, and below, are given by way of example. Alternative thin-film deposition methods may be used within the scope of the invention. The layer thicknesses are given by way of example. Alternative layer thicknesses may be used for tuning one or more parameters of e.g. the battery.

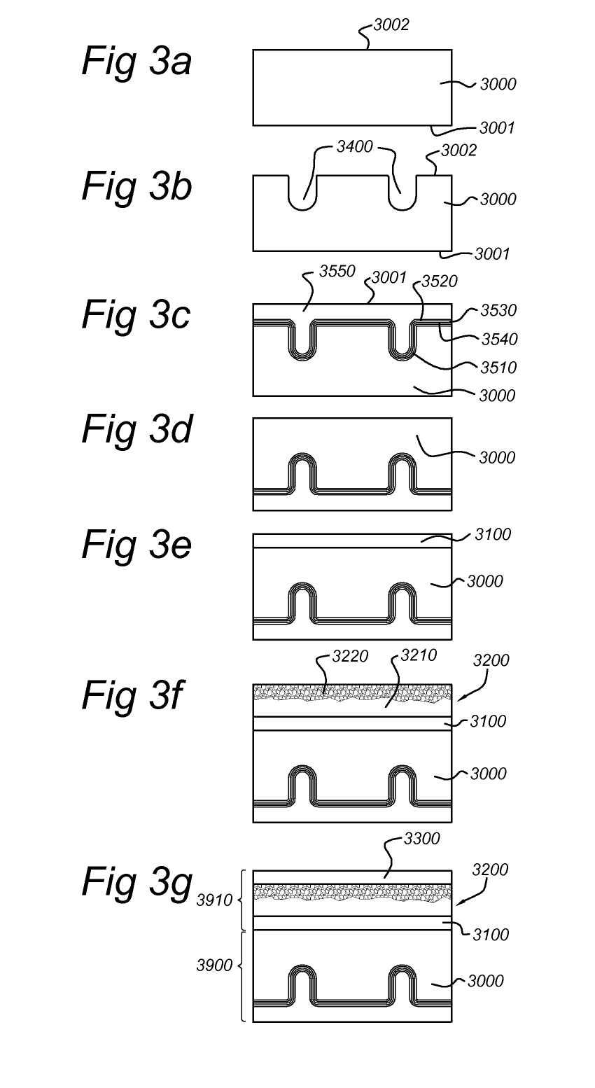

An advantage of an electrochemical solar cell is that all processing steps may be performed using coating techniques, such as electrode deposition, polymer and organic/inorganic composite coating. All these processes can be performed at temperatures lower than 200 degree C. E.g., for forming a transparent electrode, ITO is a widely used. The standard deposition temperature of crystalline ITO (c-ITO) is higher than 200 degree C. However deposition at room temperature by magnetron sputtering may be used when using amorphous ITO (a-ITO), ZnO or a-InGaZnO₄ instead of c-ITO. This allows to form first the battery and then the solar cell. An example of such a manufacturing method is shown in FIG. 3. The embodiment of the method is illustrated by showing the semiconductor device in a plurality of figures FIG. 3a-3g after each of a corresponding process stage 3A-3G.

In process stage 3A, a silicon substrate 3000 is provided. The substrate in this example is again a silicon substrate polished on both sides. The substrate has a flat surface 3001, 3002 on each side.

When the substrate is not yet provided with trenches on one surface, deep trenches 3400 are formed in an upper surface 3002 of the silicon substrate using lithography and etching as shown in process stage 3B.

In a next process stage 3C, a current collector 3510 of Pt/Ti is formed by ALD of inner walls of the trenches. A LiCoO₂ cathode layer 3540 is formed on the current collector. A LiPON solid electrolyte layer 3530 is formed on the cathode layer 3540. A silicon anode layer 3520 is formed on the solid electrolyte layer 3530. A TiN current collector layer 3550 is applied on the silicon anode layer 3520.

In a next process stage 3D, the substrate 3000 carrying the trench batteries is flipped.

In a next process stage 3E, an electrode 3100 is applied on the other surface 3001 of the silicon substrate 3000. The electrode may e.g. be platinum, deposited using e.g. ALD. Alternatively, the electrode may e.g. be a conducting polymer such as such as PEDOT:PSS, deposited using spin-coating or dip-coating.

In a next process stage 3F, an electrochemical stack 3200 is applied on the electrode 3100, comprising an electrolyte 3210 and a TiO₂ layer with dye-sensitizer 3220. In this example, the electrolyte is a solid electrolyte, but the electrolyte may also be e.g. a liquid electrolyte in a sealing material. First, the solid electrolyte 3210 is applied on the electrode 3100. In this example, the solid electrolyte comprises a polymerized I⁻/I₃⁻ system, which is applied using spin-coating and polymerization. Then, the TiO₂ layer with dye-sensitizer 3220 is applied on the solid electrolyte 3210.

In a next process stage 3G, a transparent electrode 3300 is applied on the electrochemical stack 3200. The transparent electrode 3300 may be a conducting polymer deposited using spin-coating. The transparent electrode 3300 may be ZnO or a-InGaZnO₄ deposited at room temperature by magnetron sputtering.

As a result, the electrochemical solar cell 3910 and the trench battery 3900 are formed on opposite sides of the substrate.

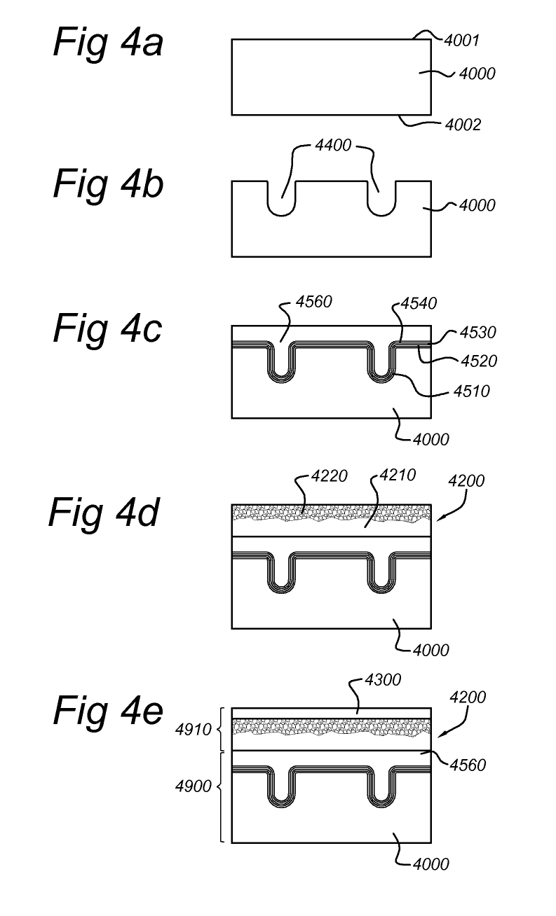

FIG. 4 shows another embodiment of a manufacturing method of a semiconductor device comprising an electrochemical solar cell and a trench battery. The embodiment of the method is illustrated by showing the semiconductor device in a plurality of figures FIG. 4a-4e after each of a corresponding process stage 4A-4E.

In process stage 4A, a silicon substrate 4000 is provided. The substrate in this example is again a silicon substrate polished on both sides. The substrate has flat surfaces 4001, 4002 on each side.

When the substrate is not yet provided with trenches on one surface, deep trenches 4400 are formed in one surface 4001 of the silicon substrate using lithography and etching as shown in process stage 4B.

In a next process stage 4C, a barrier layer 4510 of TiN is formed by sputtering on the inner walls of the trenches. A silicon anode layer 4520 is formed on the barrier layer 4510. A LiPON solid electrolyte layer 4530 is formed on the anode layer 4520. A LiCoO₂ cathode layer 4540 is formed on the LiPON solid electrolyte layer 4530. A Pt/Ti current collector layer 4560 is applied on the cathode layer 4540. This completes the forming of the battery on the first side of the substrate, In a next process stage 4D, an electrochemical stack 4200 is applied on the same side on the substrate, i.e. on top of the battery. The electrochemical stack 4200 comprises a solid electrolyte 4210 and a TiO₂ layer with dye-sensitizer 4220. First, the solid electrolyte 4210 is applied on the current collector layer 4560. In this example, the solid electrolyte is applied using spin-coating. The solid electrolyte comprises polymerized I⁻/I₃⁻ system. Then, the TiO₂ layer with dye-sensitizer 4220 is applied on the solid electrolyte 4210.

In a next process stage 4E, a transparent electrode 4300 is applied on the electrochemical stack 4200. The transparent electrode 4300 may be a-ITO, ZnO or a-InGaZnO₄ deposited at room temperature by magnetron sputtering.

As a result, the electrochemical solar cell 4910 and the trench battery 4900 are formed on the same side of the substrate.

In the example shown in FIG. 4, the electrochemical solar cell 4910 is formed immediately on top of current collector 4560 of the trench battery 4900, with the current collector 4560 also serving as the electrode of the electrochemical solar cell 4910. Alternatively, a space layer (not shown) may be applied on the current collector 4560 of the trench battery 4900 and a separate electrode (not shown) may be applied on top of the space layer to serve as the electrode of the electrochemical solar cell 4910.

In another alternative, the trench batteries are buried in the substrate.

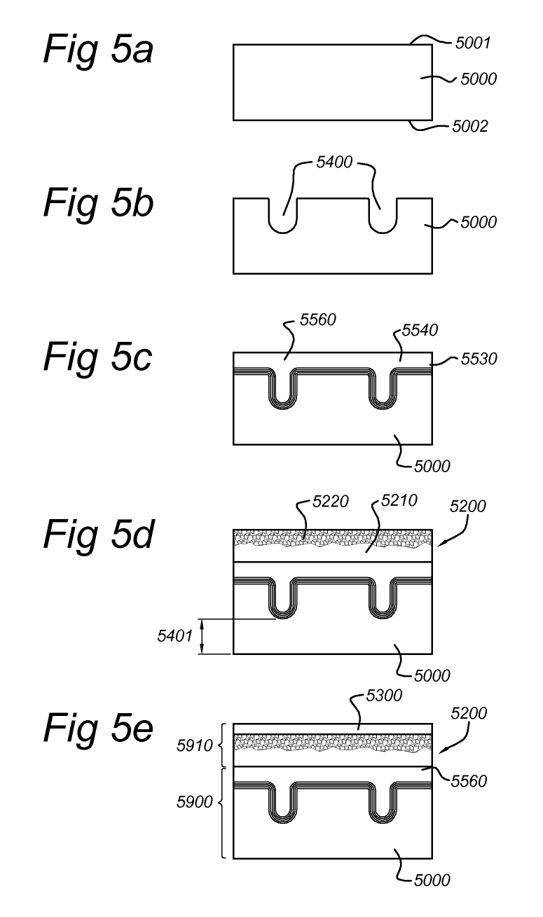

FIG. 5 shows another embodiment of a manufacturing method of a semiconductor device comprising an electrochemical solar cell and a trench battery. The embodiment of the method is illustrated by showing the semiconductor device in a plurality of figures FIG. 5a-5e after each of a corresponding process stage 5A-5E.

In process stage 5A, a silicon substrate 5000 is provided. The substrate in this example is a silicon substrate polished on both sides. The substrate has flat surfaces 5001, 5002 on each side.

In process stage 5B, deep trenches 5400 are formed in one surface 5001 of the silicon substrate using lithography and etching.

Different from FIG. 4, no barrier layer is formed on the inner walls of the trenches and no silicon anode layer is formed. Instead, the silicon substrate itself acts as the anode of the battery. This reduces the number of processing steps needed for manufacturing the semiconductor device.

Hence, in a next process stage 5C, a LiPON solid electrolyte layer 5530 is formed on the inner walls of the trenches. A LiCoO₂ cathode layer 5540 is formed on the LiPON solid electrolyte layer 5530. A Pt/Ti current collector layer 5560 is applied on the cathode layer 5540. This completes the forming of the battery on the first side of the substrate.

In this embodiment, the silicon substrate 5000 may be relatively thin. More specifically, a thickness 5401 between the bottom of the trenches and the back surface 5002 of the substrate is in a range of 100-200 nm, for preventing the lithium to diffuse to far from the battery and allowing the lithium to diffuse back to the battery.

In a next process stage 5D, an electrochemical stack 5200 is applied on the same side on the substrate, i.e. on top of the battery. In this example, the electrochemical stack 5200 comprises a solid electrolyte 5210 and a TiO₂ layer with dye-sensitizer 5220. First, the solid electrolyte 5210 is applied on the current collector layer 5560. In this example, the solid electrolyte is applied using spin-coating. The solid electrolyte comprises a polymerized I⁻/I₃⁻ system. Then, the TiO₂ layer with dye-sensitizer 5220 is applied on the solid electrolyte 5210.

In a next process stage 5E, a transparent electrode 5300 is applied on the electrochemical stack 5200. The transparent electrode 5300 may be a-ITO, ZnO or a-InGaZnO₄ deposited at room temperature by magnetron sputtering.

As a result, the electrochemical solar cell 5910 and the trench battery 5900 are formed on the same side of the substrate.

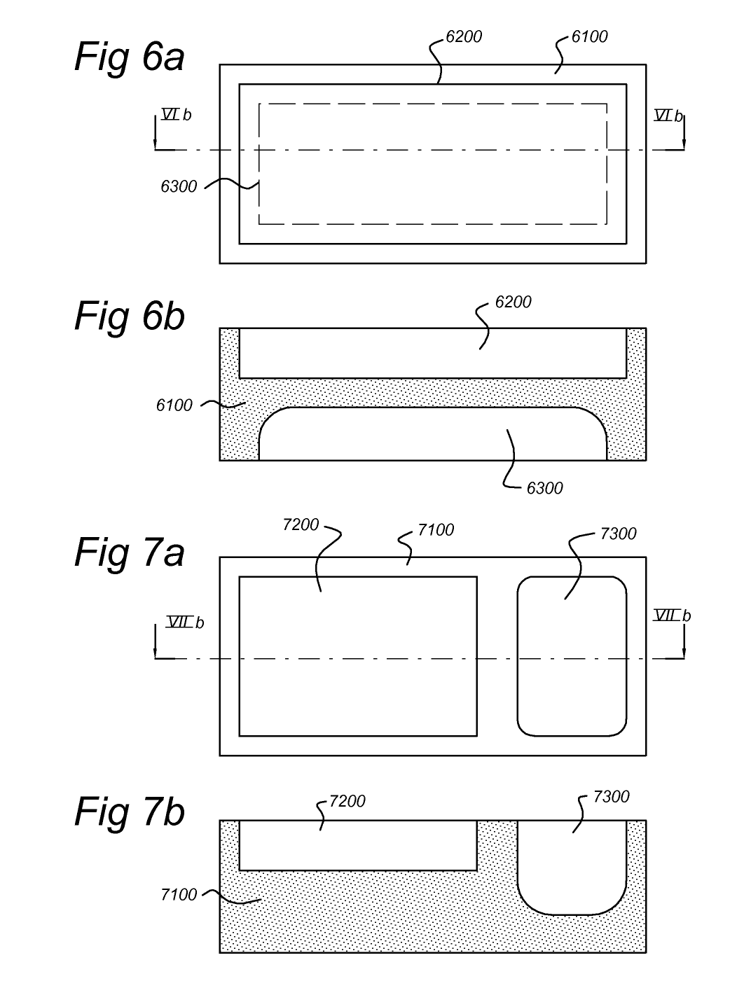

FIG. 6a and FIG. 6b schematically shows an embodiment of a semiconductor device comprising a solar cell 6200 and a trench battery 6300 formed on a substrate 6100. The solar cell may be an electrochemical solar cell or a silicon solar cell. The substrate may be a single-crystalline silicon substrate. The substrate may alternatively be e.g. a multi-crystalline silicon substrate. FIG. 6a shows a top view of the semiconductor device, whereas FIG. 6b shows a cross-section along the line VIb.

The solar cell 6200 is formed on the upper side of the substrate 6100 and uses substantially the whole area of the upper side of the substrate 6100, thus maximizing the light receiving performance.

The trench battery 6300 is formed on the lower side of the substrate 6100. To maximize the storage capacity, the trench battery is extending over substantially the whole area of the lower side of the substrate 6100.

The semiconductor device thus provides a solar cell integrated with a battery in a highly compact form, utilizing the substrate with maximum efficiency.

FIG. 7a and FIG. 7b schematically shows an embodiment of a semiconductor device comprising a solar cell 7200 and a trench battery 7300 formed on a substrate 7100. The solar cell may be an electrochemical solar cell or a silicon solar cell. The substrate may be a single-crystalline silicon substrate. The substrate may alternatively be e.g. a multi-crystalline silicon substrate. FIG. 7a shows a top view of the semiconductor device, whereas FIG. 7b shows a cross-section along the line VIIb.

The solar cell 7200 is formed on the upper side of the substrate 7100.

The trench battery 7300 is formed next to the solar cell on the same side of the substrate 7100 and uses the substantially the remaining area of the upper side of the substrate 7100.

The configuration of FIG. 7 allows to perform all processing on the same side of the substrate. This allows to use standard silicon substrates, polished on one side. This allows standard IC processing.

The semiconductor device thus provides a solar cell integrated with a battery in a compact form with a balanced cost-performance.

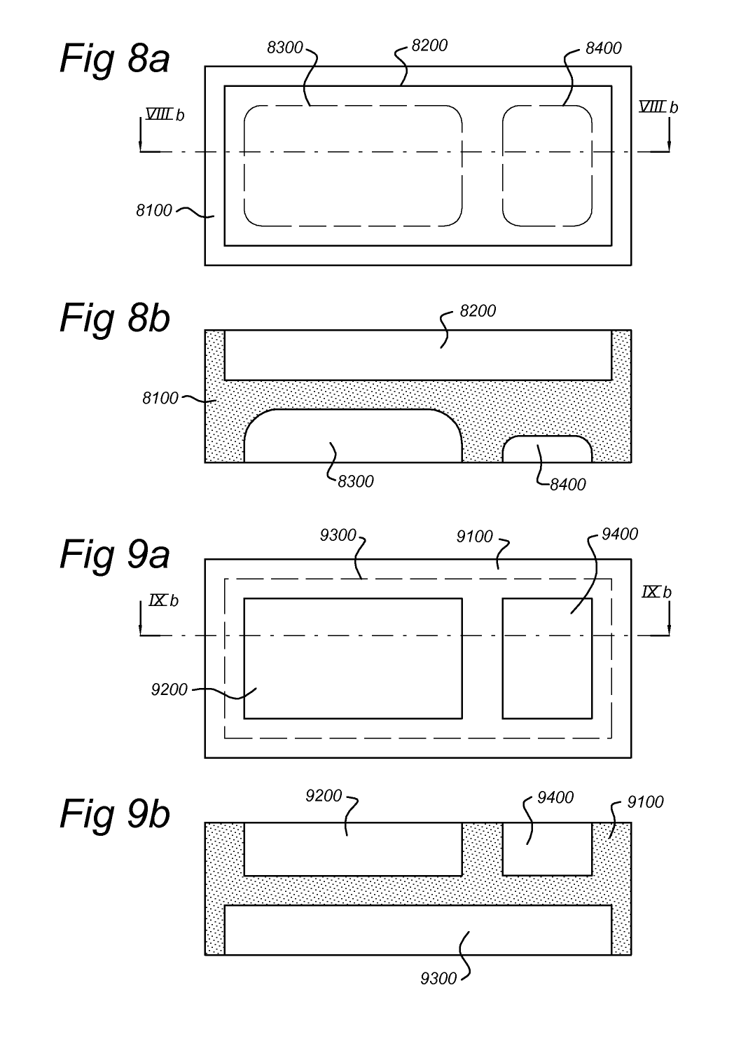

FIG. 8a and FIG. 8b schematically shows an embodiment of a semiconductor device comprising a solar cell 8200, a trench battery 8300 and CMOS circuitry 8400 formed on a substrate 8100. The solar cell may be an electrochemical solar cell or a silicon solar cell. The substrate may be a single-crystalline silicon substrate. FIG. 8a shows a top view of the semiconductor device, whereas FIG. 8b shows a cross-section along the line VIIIb.

The solar cell 8200 is formed on the upper side of the substrate 8100 and uses substantially the whole area of the upper side of the substrate 8100, thus maximizing the light receiving performance.

The trench battery 8300 is formed on the lower side of the substrate 8100. The trench battery is extending over the major part of the area of the lower side of the substrate 8100.

The CMOS circuitry 8400 is also formed on the lower side of the substrate 8100. During manufacturing of the CMOS circuitry, process stages with high-temperature treatments are performed before forming temperature-sensitive process stages associated with forming the trench battery.

The CMOS circuitry 8400 may comprise e.g. an integrated circuit monitoring element capable of, during use, monitoring at least one condition of the group consisting of a condition of the solar cell, a condition of the battery and a condition of a relation between the solar cell and the battery, and of providing monitoring information from monitoring the at least one condition.

The CMOS circuitry 8400 may comprise e.g. an integrated circuit power regulator element capable of, during use, controlling an electrical power provided from the solar cell and the battery.

The integrated power regulator element may alternatively, or additionally, control powering other integrated circuits in the semiconductor device.

The CMOS circuitry 8400 may comprise e.g. a sensor, the sensor being electrically connected to the solar cell and to the battery. The sensor may be any type of suitable sensor. For example, the sensor may e.g. be capable of sensing an external signal, such as a radio signal, of sensing an ambient condition, such as a temperature, or of sensing an parameter of a body, arranged closely to the sensor or in contact with the sensor, such as a body temperature. The body may be e.g. a human body for monitoring a physical parameter of a person, or a mechanical body, e.g. a part of an apparatus, for monitoring e.g. whether the part of the apparatus remains at a sufficiently low temperature. As another example, the sensor may be arranged for sensing an exhaust gas of an engine of a vehicle or for sensing indoor gases inside e.g. a room or a vehicle. The sensor may be applied in a vehicle for sensing e.g. a speed of the vehicle, sensing an acceleration or sensing a vibration. The sensor may be applied with a tire of a vehicle for sensing an air pressure of a tire, e.g. as part of a safety system of an automobile. The sensor may be arranged for sensing a wear of a component of a mechanical system.

The semiconductor device thus provides a solar cell integrated with a battery and CMOS circuitry in a highly compact form, utilizing the substrate with a high efficiency and exploiting the possibility of integrating further functionality with the CMOS circuitry.

FIG. 9a and FIG. 9b schematically shows an embodiment of a semiconductor device comprising a solar cell 9200, a trench battery 9300 and CMOS circuitry 9400 formed on a substrate 9100. The solar cell may be an electrochemical solar cell. The solar cell may be a silicon solar cell, e.g. a crystalline silicon solar cell, an amorphous silicon solar cell or a compound semiconductor solar cell. The substrate may be a single-crystalline silicon substrate. FIG. 9a shows a top view of the semiconductor device, whereas FIG. 9b shows a cross-section along the line IXb.

The solar cell 9200 is formed on the upper side of the substrate 9100 and uses a large part of the area of the upper side of the substrate 9100.

The CMOS circuitry 9400 is also formed on the upper side of the substrate 9100. Manufacturing of the CMOS circuitry 9400 and manufacturing of the solar cell 9200 may be performed in a single process flow, especially when the solar cell is a silicon solar cell, as the process stages for forming CMOS circuitry and for forming a silicon solar cell are very similar, using similar dopant process stages, diffusion process stages and lithographic process stages for forming metallic and active structures.

The trench battery 9300 is formed on the lower side of the substrate 9100. The trench battery is extending over substantially the whole area of the lower side of the substrate 9100, thus maximizing the energy storage capacity.

The trench battery 9300 may be formed after the solar cell 9200 and the CMOS circuitry 9400, thus performing process stages with high-temperature treatments, associated with e.g. diffusion and annealing, before forming temperature-sensitive process stages associated with forming the trench battery.

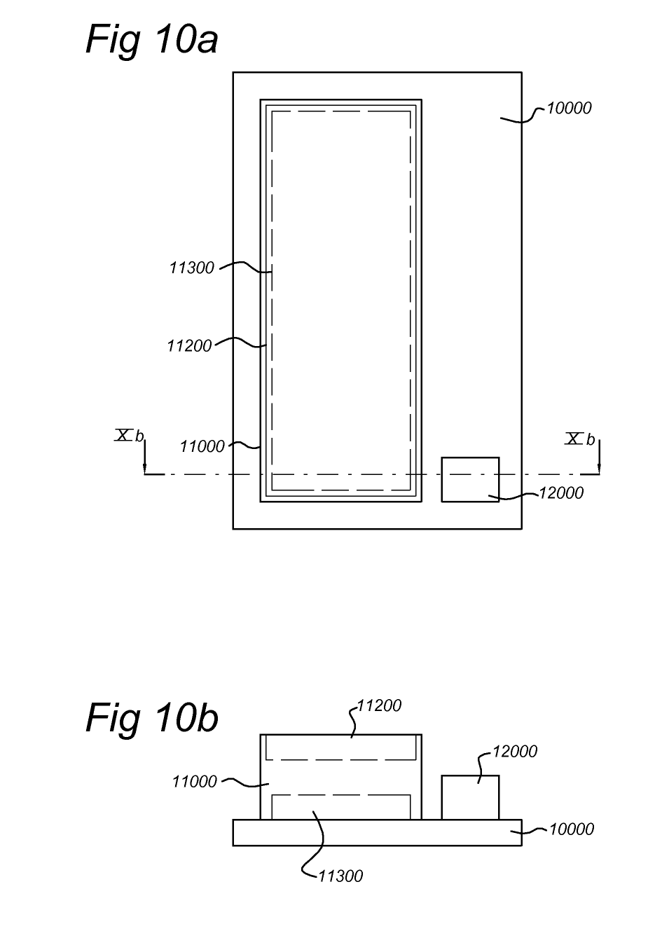

FIG. 10a and FIG. 10b schematically shows an embodiment of a multi-chip package comprising a semiconductor device 11000 and a further device 12000. FIG. 10a shows a top view of the multi-chip package, whereas FIG. 10b shows a cross-section along the line Xb.

The semiconductor device 11000 comprises a solar cell 11200 and a trench battery 11300, and optionally CMOS circuitry, formed on a substrate. The solar cell may be an electrochemical solar cell or a silicon solar cell.

The semiconductor device 11000 and the further device 12000 are mounted on a carrier 10000. In this example, the carrier is a small printed circuit board. The carrier may alternatively be e.g. a silicon carrier, optionally comprising integrated circuits, or a ceramic carrier.

In this example, the further device 12000 is a CMOS device, comprising a simple microprocessor and an integrated sensor. The CMOS device is electrically connected to the semiconductor device 11000. The microprocessor is, during use, energized from the semiconductor device 11000 and arranged to readout the sensor to obtain sensor signals and to communicate the sensor signals to an external receiver.

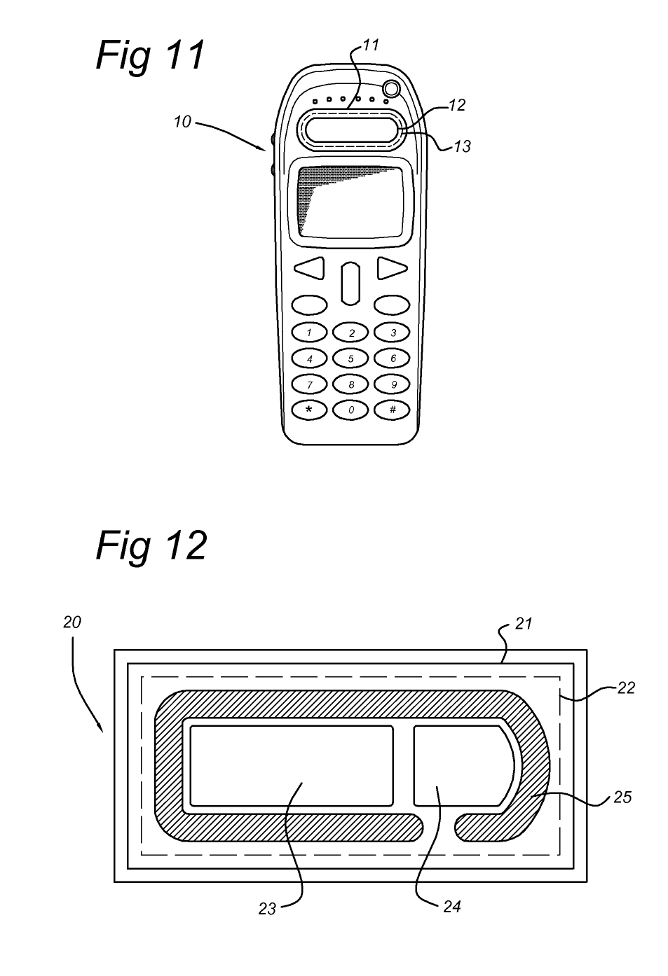

FIG. 11 shows a mobile phone 10 comprising a semiconductor device 11. The semiconductor device 11 comprises a solar cell 12 and a trench battery 13. The solar cell 12 is arranged to charge the battery 13. The battery is arranged to energize the mobile phone.

FIG. 12 shows a wireless sensor 20 comprising a semiconductor device 21. The semiconductor device 21 comprises a solar cell 22, a trench battery 23, a sensor 24 and an antenna 25. The solar cell 22 is arranged to charge the battery 23. The battery is arranged to energize the wireless sensor. In this example, the sensor is arranged to sense a body temperature of a human being when attached onto a human's skin. The solar cell may be arranged to provide the battery with sufficient capacity for energizing the sensor also when used inside a house, and not just when used outside in bright sunlight. The antenna is arranged to provide the sensed body temperature to a wireless network, capable of receiving the provided sensed body temperature. The wireless network may be used to monitor a plurality of humans, or a plurality of wireless sensors sensing different body parameters on a single human. The wireless network may be an in-car network, for e.g. acquiring sensor signals from a plurality of sensors for sensing driver safety-related parameters such as a speed and an acceleration of the car and tire pressure.

It should be noted that the above-mentioned embodiments illustrate rather than limit the invention, and that those skilled in the art will be able to design many alternative embodiments without departing from the scope of the appended claims. E.g., alternative deposition techniques may be used than those explicitly mentioned without departing from the scope of the invention and the appended claims. Likewise, the invention may apply to alternative types of solar cells not mentioned explicitly in the text. In the claims, any reference signs placed between parentheses shall not be construed as limiting the claim.

1. Semiconductor device comprising:
a substrate,
a solar cell formed on the substrate,
a battery formed on the substrate, the battery comprising a plurality of trench batteries in a plurality of corresponding trenches in the substrate.

2. Semiconductor device according to claim 1, further comprising:
an integrated circuit monitoring element capable of, during use,
monitoring at least one condition of a group consisting of a condition of the solar cell, a condition of the battery and a condition of a relation between the solar cell and the battery, and
providing monitoring information from monitoring the at least one condition.

3. Semiconductor device according to claim 1, further comprising:
an integrated circuit power regulator element capable of, during use,
controlling an electrical power provided from at least one of the solar cell and the battery.

4. Semiconductor device according to claim 1, further comprising a sensor, the sensor being electrically connected to the solar cell and to the battery.

5. Semiconductor device according to claim 1, wherein the silicon substrate is a single-crystalline silicon substrate.

6. Semiconductor device according to claim 1, wherein the battery has a storage capacity in a range of 0.1-10 mC/mm².

7. Multi-chip package comprising a semiconductor device according to claim 1 and a further semiconductor device electrically connected to the semiconductor device and being, during use, energized from the semiconductor device.

8. A method of manufacturing a semiconductor device comprising a solar cell and a battery, the method comprising:
providing a substrate;
forming the solar cell on the substrate; and
forming the battery as a plurality of trench batteries to a plurality of corresponding trenches in the substrate.

9. Method according to claim 8, further comprising:
forming an integrated circuit on the substrate, wherein at least one of forming the integrated circuit on the substrate and forming the solar cell on the substrate comprises one or more high-temperature treatments; and
wherein at least part of forming the battery is performed after all high-temperature treatments; further comprising:
forming the plurality of trenches in the substrate, wherein forming the solar cell is at least partly performed before forming the battery,
wherein:
the solar cell is formed onto a first side of the substrate in a first IC-process, the solar cell comprising a silicon solar cell comprising a plurality of p-n junctions for, during use, receiving incident light and converting at least part of the received incident light into an electrical current;
the battery is formed onto the other side of the substrate in a second IC-process.

10. Method according to claim 8, wherein:
all the solar cell is formed onto a first side of the substrate in a first IC-process, the solar cell comprising an electrochemical cell for, during use, receiving incident light and converting at least part of the received incident light into an electrical current;
the battery is formed onto the other side of the substrate in a second IC-process.

11. Method according to claim 8, wherein forming the solar cell is at least partly performed after forming the battery.

12. Method according to claim 11, wherein:
the battery is formed onto a first side of the substrate in a first IC-process;
the solar cell is formed in a second IC process, the solar cell comprising an electrochemical cell for, during use, receiving incident light and converting at least part of the received incident light into an electrical current.

13. Apparatus comprising a semiconductor device according claim 1.
